(19) United States
(12) Patent Application Publication
(10) Pub. No.: US 2011/0105189 A1
(43) Pub. Date: May 5, 2011

(54) ELECTRONIC DEVICE

(75) Inventors: CHENG HAO LEE, Hsinchu City (TW); Tzu-Ming Wang, Hsinchu City (TW); Chi Tsan Shen, Hsinchu City (TW); Gwo-Feng Hwang, Hsinchu City (TW)

(73) Assignee: Prime View International Co., Ltd., Hsinchu City (TW)

(21) Appl. No.: 12/752,477

(22) Filed: Apr. 1, 2010

(30) Foreign Application Priority Data
Oct. 30, 2009 (TW) 098137018

(51) Int. Cl. H04B 1/38; H05K 5/00; G06F 1/16; H04M 1/00

(52) U.S. Cl. 455/566; 361/679.01; 361/679.04; 455/575.3

(57) ABSTRACT

An electronic device is provided. The electronic device including a body having a side on which an unstable display is disposed and an other side on which a bi-stable display is disposed.

### FIELD OF THE INVENTION

The present invention relates to an electronic device having multiple screens. More particularly, the present invention relates to an electronic device having an unstable display and a bi-stable display at the same time.

### BACKGROUND OF THE INVENTION

With the rapid development of the electric technology, various portable electronic products, such as personal digital assistance (PDA), electronic book, cell phone and the like enriching the relevant electric products consuming market, are invented and thus satisfy versatile demands for human's life and entertainments. Such portable electronic de products vices are mainly designed to display data, characters and graphs.

For designing of these portable electronic products, it gets used to configure multiple flat displays in a single electronic product. However, the display itself is a kind of power consuming equipment, particularly for an unstable display. If a plurality of screens is designed to operate in a single electronic product, such electronic product having multiple displays must become power-consuming.

Taiwan Patent No. I309711 discloses a satellite global positioning system (GPS) device having multiple screens. Please refer to FIG. 5, which is a diagram illustrating the representative drawing for Taiwan Patent No. I309711. The satellite GPS 500 in FIG. 5 has a first host 110 and a second host 130 which are connected to each other by a pivot 140. In order to demonstrate much more information, a first liquid crystal display (LCD) 120 and a second LCD 150 are respectively disposed on the first host 110 and the second host 130. However, since it consumes considerable battery power for driving the first LCD 120 and the second LCD 150, while the satellite GPS 500 is used for displaying same contents or static contents for a long period, it becomes energy-consuming and environment-harming.

In order to overcome the drawbacks in the prior art, an electronic device having a hi-stable display is thus provided. The particular design in the present invention not only solves the problems described above, but also is easy to be implemented. Thus, the invention has the utility for the industry.

### SUMMARY OF THE INVENTION

The present invention provides an electronic device having multiple screens in combination with a bi-stable display and an unstable display. Since a bi-stable display is integrated in the device, the screen of the device is capable to demonstrate a specific contents for a long period without power supply. Therefore the mentioned electronic device can distribute a static displaying contents or a contents that needs to be demonstrated for a long time to be shown on the bi-stable display, to significantly reduce the power consuming for prevent harming environment at the same time. Furthermore, the bi-stable display of the multiple screen electronic device having bi-stable display disclosed in the present invention can be utilized as an identification after configured appropriately.

In accordance with the first aspect of the present invention, an electronic device is provided. The electronic device includes a body having a side on which an unstable display is disposed and an other side on which a bi-stable display is disposed.

Preferably, the electronic device further includes a switching element configured on the body and switching the unstable display and the bi-stable display to operate between a synchronization mode and a non-synchronization mode.

Preferably, the body further has an electronic computing module therein.

Preferably, the electronic computing module further includes a processor processing a received data and a storing medium storing one of the received data and a processed data.

Preferably, the other side is one of an opposite side opposite to the side and an edge side beside to the side.

Preferably, the bi-stable display is one selected from a group consisting of a micro-electro-mechanical system display, an electro-phonetic display, a reflective-display, an electronic paper and a combination thereof.

Preferably, the unstable display is one selected from a group consisting of a liquid crystal display, an electrowetting display, a plasma display and a combination thereof.

Preferably, each of the bi-stable display and the unstable display is one selected from a group consisting of a touch-based display, a flexible display and a soft display.

Preferably, the electronic device is one selected from a group consisting of a notebook computer, a digital camera, a personal digital assistance, a global positioning system, an electronic book, a mobile communication equipment, a audio-video player, a portable electronic device, a miniature computing device, a digitalized processing device and a handheld electronic device.

In accordance with the second aspect of the present invention, an electronic device is provided. The electronic device including a first body having a first surface disposing thereon a first unstable display; and a second body rotatably connected with the first body and having a second surface disposing thereon a first bi-stable display.

Preferably, the second body is electrically connected with the first body.

Preferably, the second body further includes a third surface opposite to the second surface disposing thereon one of a second unstable display and a second bi-stable display.

Preferably, one of the first and the second bi-stable displays is configured as an identification.

Preferably, the electronic device is one of a foldable electronic device or a twistable electronic device.

Preferably, the foldable electronic device is a foldable mobile phone and the twistable electronic device is a twistable mobile phone.

In accordance with the third aspect of the present invention, an electronic device is provided. The electronic device including a first body having a first surface disposing thereon a first unstable display; and a second body slidably connected with the first body and having a second surface disposing thereon a first bi-stable display.

Preferably, the second body is electrically connected with the first body.

Preferably, the second body further includes a third surface opposite to the second surface and disposing thereon one of a third surface a second unstable display and a second bi-stable display.

Preferably, the electronic device is one of a slidable electronic device and a twistable electronic device.

Preferably, the slidable electronic device is one of a slidable mobile phone and a slidable electronic dictionary.

Other objects, advantages and efficacy of the present invention will be described in detail below taken from the preferred embodiments with reference to the accompanying drawings, in which:

### BRIEF DESCRIPTION OF THE DRAWINGS

FIGS. 1(a) and 1(b) are diagrams illustrating a first embodiment of the electronic device according to the present invention;

FIGS. 2(a) and 2(b) are diagrams illustrating a second embodiment of the electronic device according to the present invention;

FIGS. 3(a) and 3 (b) are diagrams illustrating a third embodiment according to the present invention;

FIG. 4 is a diagram illustrating a fourth embodiment according to the present invention; and

FIG. 5 is a diagram illustrating the representative drawing for Taiwan Patent No. I309711.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purposes of illustration and description only; it is not intended to be exhaustive or to be limited to the precise form disclosed.

An unstable display refers to a displaying device that continues displaying contents under condition that electric power is continuously supplying thereto. Once the electric power is disconnected, the contents showing on the screen of the unstable display disappears. A bi-stable display refers a displaying device that is capable to display contents on the screen for quite a period while even electric power does not supply thereto. Once the electric power is disconnected the contents showing on the screen of the unstable display disappears. For a bi-stable display, the electric power is just used for driving the electrophoresis particles so as to update the displaying contents. For a bi-stable display, when the electric power is shut down, the displaying contents stays in the last updated contents. Usually, a bi-stable display is preferably capable to display an unvaried contents for lasting almost one month, which is suitable for a demand displaying a static contents or an application occasion that needs a long-term demonstration.

Typically, a bi-stable display is preferably a bi-stable liquid crystal display (LCD), a micro-electro-mechanical system (MEMS) display, an electro-phoretic display (EPD), a reflective-display or an electronic paper. A stable display is preferably an unstable LCD, an electrowetting display or a plasma display. At the same time, the mentioned bi-stable display and the unstable display preferably a touch-based display having a touch panel disposed thereon, a flexible display or a soft display.

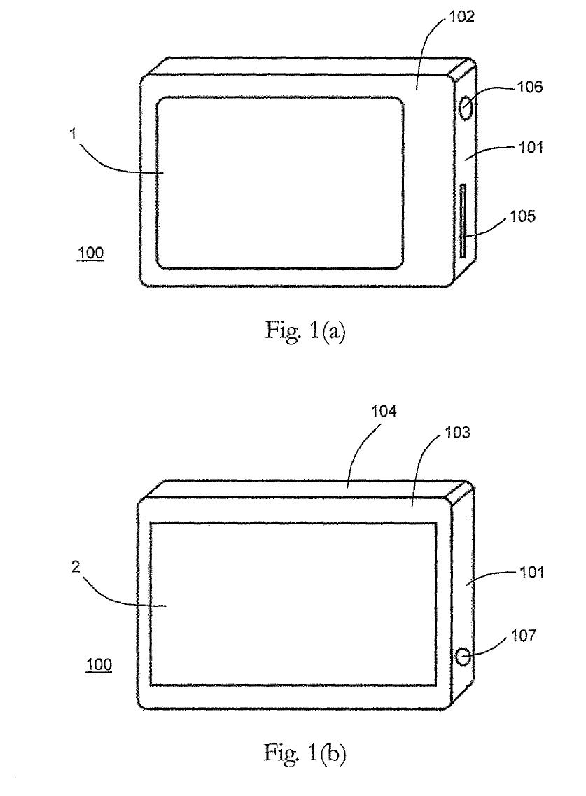

Please simultaneously direct to FIGS. 1(a) and 1(b), which are diagrams illustrating a first embodiment of the electronic device according to the present invention. The electronic device 100 in FIG. 1 is preferably a notebook (NB) computer, a digital camera (DC), a personal digital assistance (PAD), a global positioning system (GPS), an electronic book (e-book), a mobile communication equipment, a audio-video player, a portable electronic device, a miniature computing device, a digitalized processing device or a handheld electronic device, in which a digital processing module is disposed. The fundamental architecture of the mentioned digital processing module in the electronic device 100 includes at least a central processing unit (CPU, not shown in Figs.), at least a storing medium (not shown in Figs.) at least one set of input/output component and a power unit. The CPU is used for receiving and processing data and the storing medium is used for storing the received data or processed data. Basically, the connecting and operating relationships among the above-mentioned components are well known by a person skilled in the art.

A host 101 of the electronic device 100 has a first side 102 and a second side 103 opposite to the first side 102. An unstable display 1 is disposed on the first side 102 and a bi-stable display 2 is disposed on the second side 103. The unstable display 1 disposed on the first side 102 are commonly suitable for displaying a dynamic contents and the bi-stable display 2 disposed on the second side 103 are commonly suitable for displaying a static contents. For instance, while the electronic device 100 is preferably a GPS, the unstable display 1 on the first side 102 is suitable for displaying a digital map having much dynamic displaying contents since the map is dynamically altered in response to movement of a user. The bi-stable display 2 on the second side 103 is used for displaying for instance an email or an e-book having much static displaying contents. Specifically, a user can directly utilize such GPS having two screens to obtain a real-time geographic road information by a LCD on the first side and read e-mail or e-book by the EPD on the second side simultaneously. Additionally, the electronic device 100 could be preferably a handheld digital television player, where a LCD on front side is used for playing TV program and an EPD on back side is used for displaying e-mail or e-book simultaneously.

The host 101 of the electronic device 100 further includes a switch 106 for switching the unstable display 1 and the bi-stable display 2 to operate between a synchronization mode and a non-synchronization mode. While a synchronization mode is switched, the displaying contents on the respective unstable display 1 and bi-stable display 2 are associated to become an integration. While a non-synchronization mode is switched, the displaying contents on the respective unstable display 1 and bi-stable display 2 are irrelevant. It is noted that the bi-stable display 2 can be disposed on the lateral side 104 of the host 101. Several function components such as, an expansion slot 105 and an ear phone socket 107, are preferably further disposed on the host 101.

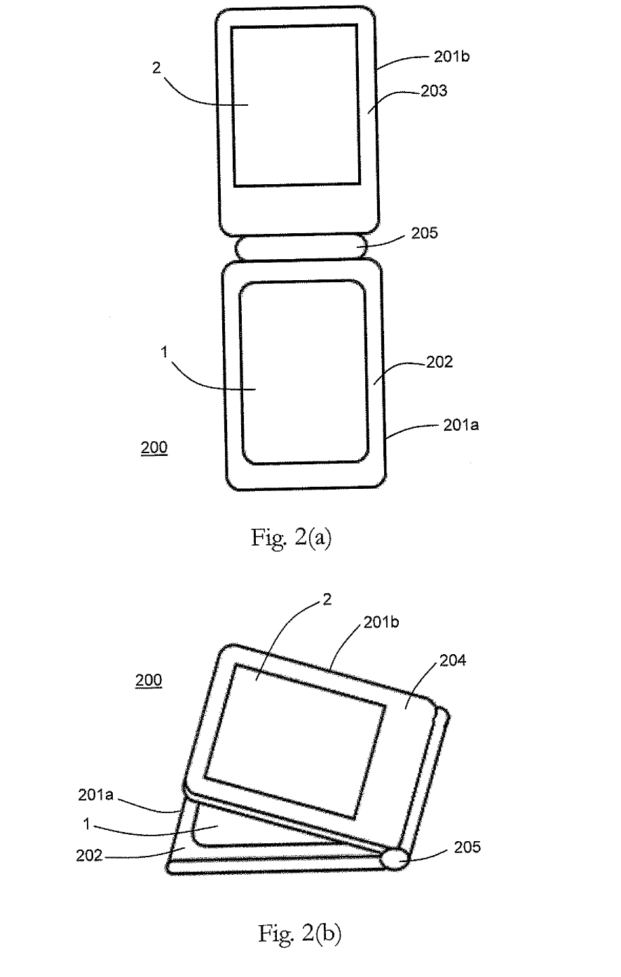

Please further direct to FIGS. 2(a) and 2(b), which are diagrams illustrating a second embodiment of the electronic device according to the present invention. The first surface 202 of the first host 201a of the electronic device 200 has an unstable display 1 and the front surface 203 of the second host 201b has a bi-stable display 2. The first host 201a and the second host 201b are rotatably connected with each other by a rotating mechanism 205, preferably a pivot component or a hinge component and in the mean time, the first host 201a and the second host 201b are also electronically connected with each other.

The above-mentioned bi-stable display 2 can be optionally disposed on the back side 204 of the second host 201b. That is the bi-stable display 2 can be disposed on the front side 203 or the back side 204 opposite to the front side 203. Preferably, two bi-stable display 2 can be disposed on both front side 203 and back side 204 of the second host 201b at the same time. In addition, the bi-stable display 2 can be preferably disposed on one of front side 203 and the back side 204 and an unstable display 1 is then disposed on the other one. Several function components such as, an expansion slot and a volume bottom, are preferably further disposed on the second host 201b. Specifically, the electronic device 200 is preferably a foldable electronic device or a twistable electronic device, for instance, a foldable cell phone or a twistable cell phone.

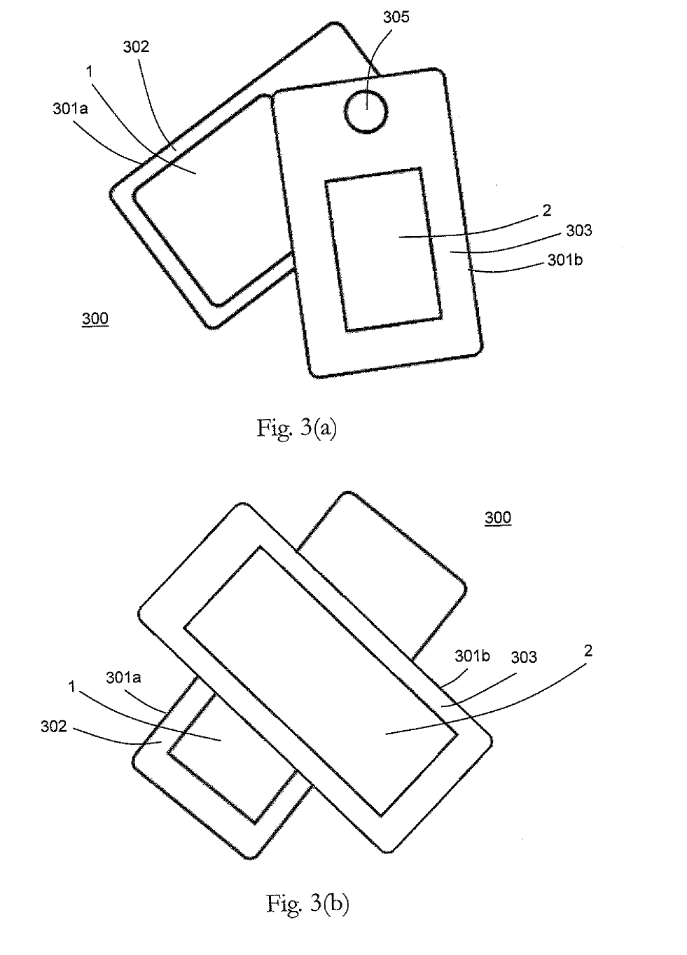

On the basis of the above-mentioned second embodiment, a third embodiment is correspondingly derived. Please direct to FIG. 3(a), which is a diagram illustrating a third embodiment according to the present invention. The front surface 302 of the first host 301a of the electronic device 300 has an unstable display 1 and the back surface 303 of the second host 301b has a bi-stable display 2. The first body 301a and the second body 301b are rotatably connected with each other by a rotating mechanism 305, preferably a pivot component or a hinge component and in the mean time, the first body 301a and the second body 301b are also electronically connected with each other.

The above-mentioned bi-stable display 2 can be optionally disposed on the front surface (not shown in FIG. 3(a)) of the second body 301b. That is the bi-stable display 2 can be disposed on the back surface 303 or the front surface opposite to the back surface 303. Preferably, two bi-stable display 2 can be disposed on both back surface 303 and front surface of the second body 301b at the same time. In addition, the bi-stable display 2 can be preferably disposed on one of back surface 303 and front surface and an unstable display 1 is then disposed on the other one. In addition to display information, the bi-stable display 2 in the third embodiment could be duly configured as an identification for the electronic device 300 which operates with respect to the order transmitted from the digital processing module in the electronic device 300. Specifically, the electronic device 300 is preferably a rotatable electronic device or a twistable electronic device, for instance a commonly twistable cell phone.

It is noted that the rotating mechanism 305 is not limited to be disposed at position approximate to the edge of the first host 301a and the second host 301b. The rotating mechanism 305 can also be disposed at position approximate to the center of the first host 301a and the second host 301b, which is shown in FIG. 3(b).

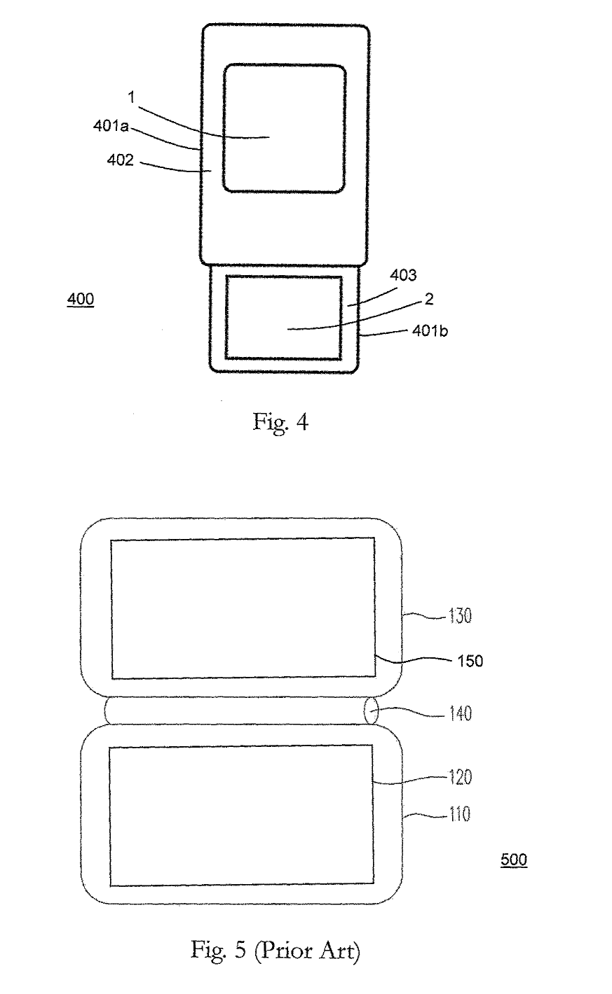

Please resume directing to FIG. 4, which is a diagram illustrating a fourth embodiment according to the present invention. The first surface 402 of the first host 401a of the electronic device 400 has an unstable display 1 and the front surface 403 of the second host 401b has a bi-stable display 1 The first host 401a and the second host 401b are rotatably connected with each other by a slidable mechanism (not shown in FIG. 4), preferably a track suite or a slidable track suite and in the mean time, the first host 401a and the second host 401b are also electronically connected with each other.

The above-mentioned bi-stable display 2 can be optionally disposed on the back surface (not shown in FIG. 4) of the second host 401b. That is the bi-stable display 2 can be disposed on the front surface 403 or the back surface opposite to the front surface 403. Preferably, two bi-stable display 2 can be disposed on both front surface 403 or back surface of the second host 401b at the same time. In addition, the bi-stable display 2 can be preferably disposed on one of the front surface 403 or the back surface and an unstable display 1 is then disposed on the other one. Specifically, the electronic device 400 is preferably a slidable electronic device, for instance a commonly slidable cell phone or a slidable electronic dictionary. The appearance of the slidable electronic dictionary is a transverse elongated rectangular.

While the invention has been described in terms of what is presently considered to be the most practical and preferred embodiments, it is to be understood that the invention needs not be limited to the disclosed embodiments. Therefore, it is intended to cover various modifications and similar configuration included within the spirit and scope of the appended claims, which are to be accorded with the broadest interpretation so as to encompass all such modifications and similar structures.

What is claimed is:

1. An electronic device, comprising:
a body having a side on which an unstable display is disposed and an other side on which a bi-stable display is disposed.

2. The electronic device according to claim 1 further comprising a switching element configured on the body and switching the unstable display and the bi-stable display to operate between a synchronization mode and a non-synchronization mode.

3. The electronic device according to claim 1, wherein the body further has an electronic computing module therein.

4. The electronic device according to claim 3, wherein the electronic computing module further comprises a processor processing a received data and a storing medium storing one of the received data and a processed data.

5. The electronic device according to claim 1, wherein the other side is one of an opposite side opposite to the side and an edge side beside to the side.

6. The electronic device according to claim 1, wherein the bi-stable display is one selected from a group consisting of a micro-electro-mechanical system display, an electro-phoretic display, a reflective-display, an electronic paper and a combination thereof.

7. The electronic device according to claim 1, wherein the unstable display is one selected from a group consisting of a liquid crystal display, an electrowetting display, a plasma display and a combination thereof.

8. The electronic device according to claim 1, wherein each of the bi-stable display and the unstable display is one selected from a group consisting of a touch-based display, a flexible display and a soft display.

9. The electronic device according to claim 1 being one selected from a group consisting of a notebook computer, a digital camera, a personal digital assistance, a global positioning system, an electronic book, a mobile communication equipment, a audio-video player, a portable electronic device, a miniature computing device, a digitalized processing device and a handheld electronic device.

10. An electronic device, comprising:
a first body having a first surface disposing thereon a first unstable display; and
a second body rotatably connected with the first body and having a second surface disposing thereon a first bi-stable display.

11. The electronic device according to claim 10, wherein the second body is electrically connected with the first body.

12. The electronic device according to claim 10, wherein the second body further comprises a third surface opposite to the second surface disposing thereon one of a second unstable display and a second bi-stable display.

13. The electronic device according to claim 12, wherein one of the first and the second bi-stable displays is configured as an identification.

14. The electronic device according to claim 10 being one of a foldable electronic device or a twistable electronic device.

15. The electronic device according to claim 14, wherein the foldable electronic device is a foldable mobile phone and the twistable electronic device is a twistable mobile phone.

16. An electronic device, comprising:
a first body having a first surface disposing thereon a first unstable display; and
a second body slidably connected with the first body and having a second surface disposing thereon a first bi-stable display.

17. The electronic device according to claim 16, wherein the second body is electrically connected with the first body.

18. The electronic device according to claim 16, wherein the second body further comprises a third surface opposite to the second surface and disposing thereon one of a third surface a second unstable display and a second bi-stable display.

19. The electronic device according to claim 16 being one of a slidable electronic device and a twistable electronic device.

20. The electronic device according to claim 19, wherein the slidable electronic device is one of a slidable mobile phone and a slidable electronic dictionary.
